(19) United States
(12) Patent Application Publication
(10) Pub. No.: US 2026/0052644 A1
(43) Pub. Date: Feb. 19, 2026

(54) AUTOMATED IMMERSION SYSTEM, SERVER APPARATUS OF AUTOMATED IMMERSION SYSTEM, AND CABINET OF AUTOMATED IMMERSION SYSTEM

(71) Applicant: MIRLE AUTOMATION CORPORATION, HSINCHU (TW)

(72) Inventors: Shih-Yang Chang, HSINCHU (TW); Chih-Chang Lin, HSINCHU (TW); Kuo-Ping Huang, HSINCHU (TW)

(21) Appl. No.: 19/188,017

(22) Filed: Apr. 24, 2025

Related U.S. Application Data
(60) Provisional application No. 63/682,823, filed on Aug. 14, 2024.

(30) Foreign Application Priority Data
Feb. 27, 2025 (TW) 114107220

(51) Int. Cl. H05K 7/20

(52) U.S. Cl. CPC H05K 7/20236; H05K 7/20781

(57) ABSTRACT

An automated immersion system, a server apparatus of an automated immersion system, and a cabinet of an automated immersion system. The cabinet includes a plurality of vertical insertion slots and at least one switch that is located at an outer side of the vertical insertion slots. Each of the vertical insertion slots is parallel to a vertical direction, and the vertical insertion slots are arranged in one row along a distribution direction perpendicular to the vertical direction. Each of the vertical insertion slots includes two insertion ports and two guiding grooves that are respectively arranged adjacent to the two insertion ports, and each of the two insertion ports is higher than a top opening of the corresponding guiding groove along the vertical direction. Each of the insertion ports is electrically coupled to the at least one switch.

### CROSS-REFERENCE TO RELATED PATENT APPLICATION

This application claims the benefit of priority to Taiwan Patent Application No. 114107220, filed on Feb. 27, 2025. The entire content of the above identified application is incorporated herein by reference.

This application claims the benefit of priority to the U.S. Provisional Patent Application Ser. No. 63/682,823, filed on Aug. 14, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an immersion system, and more particularly to an automated immersion system, a server apparatus of an automated immersion system, and a cabinet of an automated immersion system.

### BACKGROUND OF THE DISCLOSURE

A cabinet of a conventional immersion server system has an architecture that is difficult to implement in an automated pick and place process for servers, such that disassembly and assembly operations (e.g., plugging and unplugging cables) for the servers still need to be performed manually. In order to solve this issue, an automated immersion system, a server apparatus of an automated immersion system, and a cabinet of an automated immersion system are provided in the present disclosure, which are sensibly designed and can effectively improve on relevant issues with the conventional immersion server system.

### SUMMARY OF THE DISCLOSURE

In response to the above-referenced technical inadequacies, the present disclosure provides an automated immersion system, a server apparatus of an automated immersion system, and a cabinet of an automated immersion system for effectively improving on the issues associated with conventional cabinets of the conventional immersion server systems.

In order to solve the above-mentioned problems, one of the technical aspects adopted by the present disclosure is to provide an automated immersion system, which includes a cooling trough, a server apparatus, and a transferring mechanism. The cooling trough is configured to accommodate a cooling liquid therein. The server apparatus is disposed in the cooling trough and includes a cabinet and a server module. The cabinet includes a plurality of vertical slots and at least one switch. Each of the vertical slots is parallel to a vertical direction. The vertical slots are arranged in one row along a distribution direction perpendicular to the vertical direction, and each of the vertical slots has at least one insertion port. The at least one switch is located at an outer side of the vertical slots. The at least one insertion port of each of the vertical slots is electrically coupled to the at least one switch. The server module is detachably inserted into the cabinet so as to be located at an electrical connection position. The server module includes a server, an external connection mechanism, and a guiding mechanism. The external connection mechanism includes a handle fixed to the server, at least one electrical connection member assembled to the handle, and a signal transmission unit that is electrically coupled to the server and the at least one electrical connection member. The guiding mechanism is assembled to the server. The transferring mechanism is movable relative to the cooling trough and the server apparatus. The transferring mechanism is configured to hold the server module through the handle and to insert the server and the guiding mechanism into at least one of the vertical slots along the vertical direction, so that the at least one electrical connection member is inserted into the at least one insertion port of the at least one of the vertical slots for being located at the electrical connection position.

In order to solve the above-mentioned problems, another one of the technical aspects adopted by the present disclosure is to provide a server apparatus of an automated immersion system, which includes a cabinet and a server module. The cabinet includes a plurality of vertical slots and at least one switch. Each of the vertical slots is parallel to a vertical direction. The vertical slots are arranged in one row along a distribution direction perpendicular to the vertical direction. Each of the vertical slots has at least one insertion port. The at least one switch is located at an outer side of the vertical slots. The at least one insertion port of each of the vertical slots is electrically coupled to the at least one switch. The server module is detachably inserted into the cabinet so as to be located at an electrical connection position. The server module includes a server, an external connection mechanism, and a guiding mechanism. The external connection mechanism includes a handle fixed to the server, at least one electrical connection member assembled to the handle, and a signal transmission unit that is electrically coupled to the server and the at least one electrical connection member. The guiding mechanism is assembled to the server. The server and the guiding mechanism of the server module are configured to insert into at least one of the vertical slots along the vertical direction, so that the at least one electrical connection member is inserted into the at least one insertion port of the at least one of the vertical slots for being located at the electrical connection position.

In order to solve the above-mentioned problems, yet another one of the technical aspects adopted by the present disclosure is to provide a cabinet of an automated immersion system, which includes a plurality of vertical slots and at least one switch. Each of the vertical slots is parallel to a vertical direction. The vertical slots are arranged in one row along a distribution direction perpendicular to the vertical direction. Each of the vertical slots has two insertion ports and two guiding grooves that are respectively arranged adjacent to the two insertion ports. In any one of the vertical slots, each of the two insertion slots is higher than a top opening of an adjacent one of the two guiding grooves along the vertical direction. The at least one switch is located at an outer side of the vertical slots, and the two insertion ports of each of the vertical slots are electrically coupled to the at least one switch.

Therefore, in any one of the automated immersion system, the server apparatus, and the cabinet provided by the present disclosure, the server module can be inserted into and electrically coupled to at least one of the vertical slots along the vertical direction through the structural design of the vertical slots of the cabinet, such that the server module and the cabinet can be effectively disassembled and assembled automatically (or unmanned).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an automated immersion system according to a first embodiment of the present disclosure;

FIG. 2 is a schematic perspective view showing a subsequent movement of the automated immersion system of FIG. 1;

FIG. 3 is a schematic perspective view showing a subsequent movement of the automated immersion system of FIG. 2;

FIG. 4 is a schematic enlarged view of part IV of FIG. 1;

FIG. 5 is a schematic side view of FIG. 2;

FIG. 6 is a schematic enlarged view of a part of FIG. 5;

FIG. 7 is a schematic cross-sectional view taken along line VII-VII of FIG. 6;

FIG. 8 is a schematic enlarged view of part VIII of FIG. 7;

FIG. 9 is a schematic perspective view showing a subsequent movement of the automated immersion system of FIG. 8; and

FIG. 10 is a schematic perspective view of the automated immersion system according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

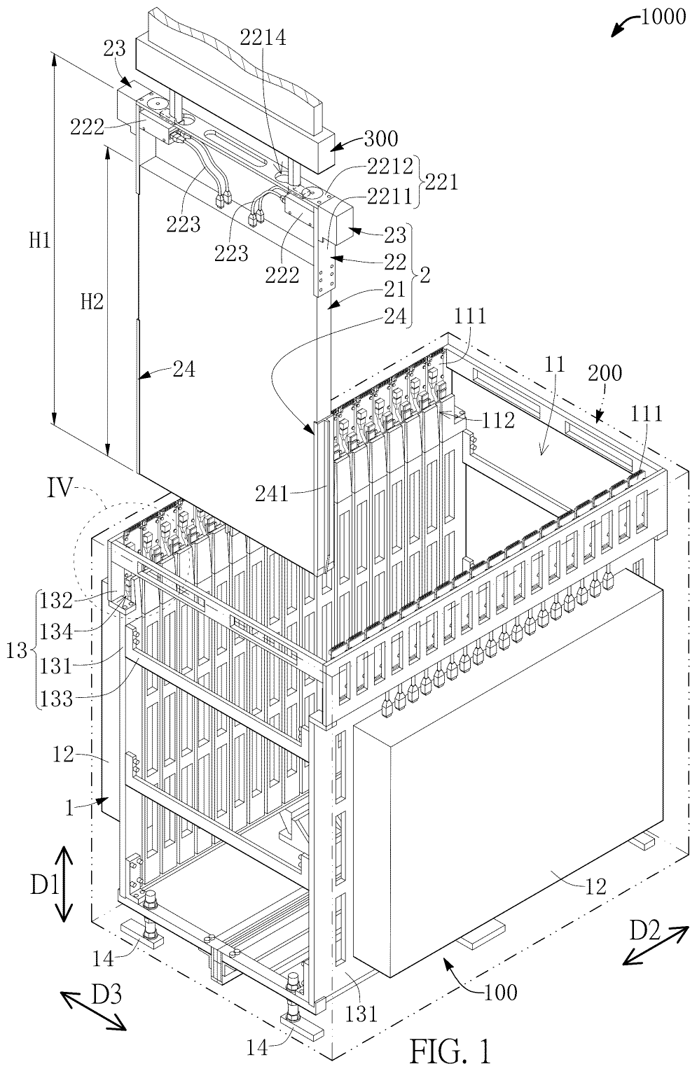

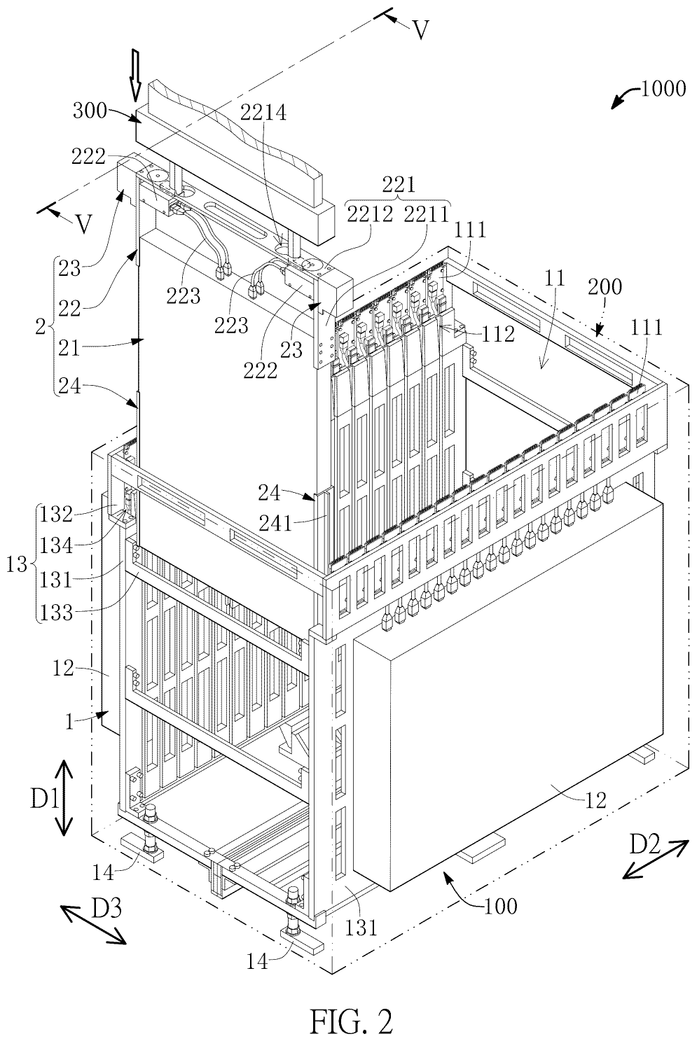

Referring to FIG. 1 to FIG. 9, a first embodiment of the present disclosure is provided. The present embodiment provides an automated immersion system 1000, which includes a cooling trough 200, a server apparatus 100 disposed in the cooling trough 200, and a transferring mechanism 300 that is movable relative to the cooling trough 200 and the server apparatus 100. The cooling trough 200 is configured to accommodate a cooling liquid (e.g., fluoride cooling liquid not shown in the drawings) therein, and a larger part of the volume of the server apparatus 100 can be immersed in the cooling liquid for heat dissipation. In other words, a server configuration not applied in an immersion environment is different from the automated immersion system 1000 (and the server apparatus 100) provided by the present embodiment.

It should be noted that the server apparatus 100 in the present embodiment is described in cooperation with the cooling trough 200 and the transferring mechanism 300, but the present disclosure is not limited thereto. For example, in other embodiments of the present disclosure not shown in the drawings, the server apparatus 100 can be independently used (e.g., sold) or can be used in cooperation with other components. The following description describes the structure of the server apparatus 100, and then describes the connection relationship of the server apparatus 100 and other components.

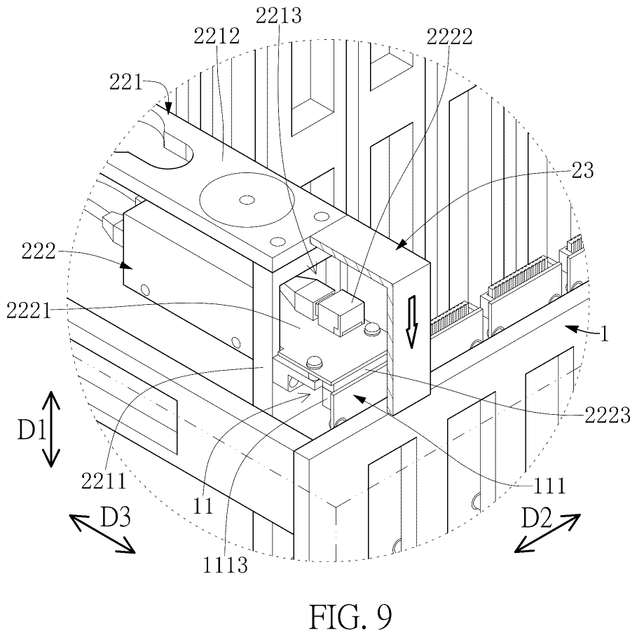

As shown in FIG. 1 to FIG. 3, the server apparatus 100 includes a cabinet 1 and at least one server module 2 that is in cooperation with the cabinet 1. In the following description of the present embodiment, the at least one server module 2 is detachably inserted into the cabinet 1 for being located at an electrical connection position (as shown in FIG. 9), but the present disclosure is not limited thereto. For example, in other embodiments of the present disclosure not shown in the drawings, the cabinet 1 can be independently used (e.g., sold) or can be used in cooperation with other components.

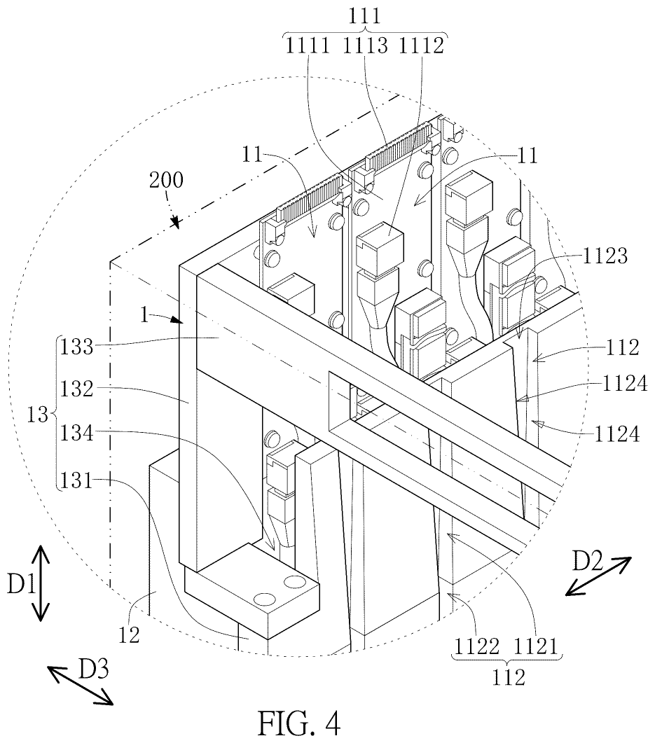

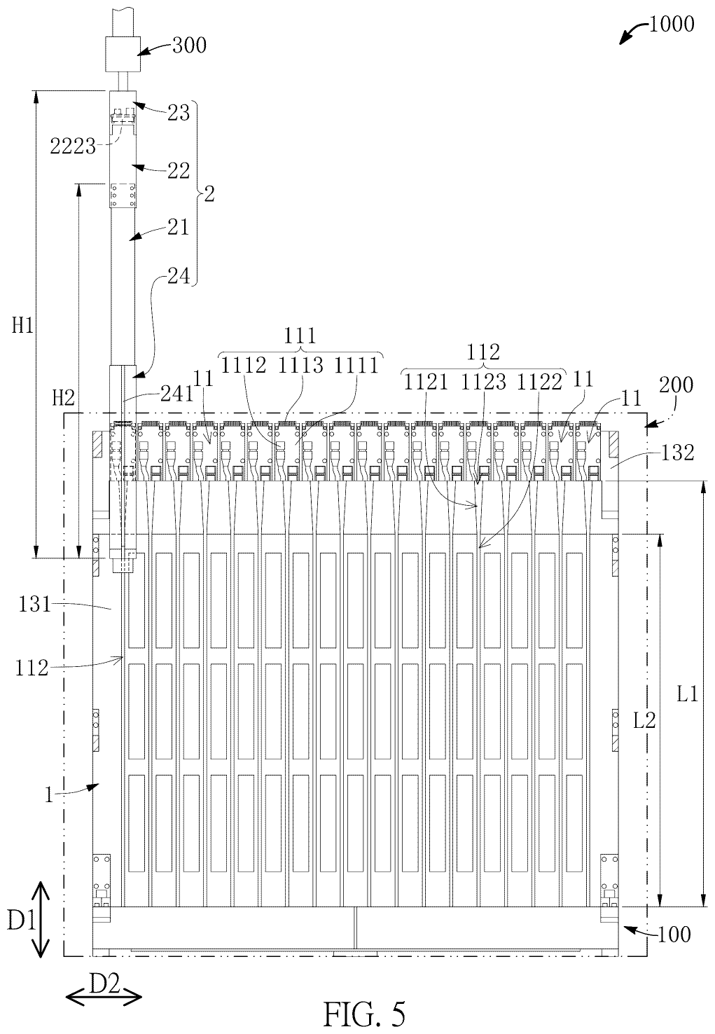

As shown in FIG. 4 and FIG. 5, the cabinet 1 includes a plurality of vertical slots 11 and at least one switch 12 that is arranged at an outer side of the vertical slots 11. Each of the vertical slots 11 is parallel to a vertical direction D1, and the vertical slots 11 are arranged in one row (at equal intervals) along a distribution direction D2 perpendicular to the vertical direction D1.

In addition, as the vertical slots 11 in the present embodiment are of substantially the same structure for providing an insertion of the at least one server module 2, the following description discloses the structure of just one of the vertical slots 11 for the sake of brevity, but the present disclosure is not limited thereto. For example, in other embodiments of the present disclosure not shown in the drawings, if the vertical slots 11 can provide the insertion of the at least one server module 2, the vertical slots 11 can be of different structures.

In the present embodiment, the vertical slot 11 has at least one insertion port 111 that is electrically coupled to the at least one switch 12, and the vertical slot 11 has two guiding grooves 112 respectively arranged on two opposite sides thereof. In other words, the two guiding grooves 112 of the vertical slot 11 face toward each other along a width direction D3 that is perpendicular to the vertical direction D1 and the distribution direction D2.

Moreover, a quantity of the at least one insertion port 111 of the vertical slot 11 in the present embodiment is two, and the two insertion ports 111 are respectively arranged adjacent to the two guiding grooves 112 and are respectively located outside of the two guiding grooves 112 along the width direction D3, but the present disclosure is not limited thereto. For example, in other embodiments of the present disclosure not shown in the drawings, each of the vertical slots 11 can be provided with only one insertion port 111, and the insertion ports 111 of the vertical slots 11 are arranged in one row along the distribution direction D2.

Moreover, a configuration of any one of the two insertion ports 111 provided by the present embodiment includes a circuit board 1111, a plurality of signal connectors 1112 mounted on the circuit board 1111, and a female connector 1113 that is mounted on a top end of the circuit board 1111. In any one of the two insertion ports 111, the signal connectors 1112 and the female connector 1113 are mounted on a same surface of the circuit board 1111, thereby reducing a volume of the insertion port 111, but the present disclosure is not limited thereto.

In addition, along the vertical direction D1, each of the two insertion ports 111 (e.g., the female connector 1113) is higher than a top opening 1123 of any one of the two guiding grooves 112 or is higher than the top opening 1123 of an adjacent one of the two guiding grooves 112, thereby enabling each of the two insertion ports 111 to be suitably connected to the server module 2.

Specifically, since the two guiding grooves 112 of the vertical slot 11 in the present embodiment are mirror-symmetrical relative to each other, the following description discloses the structure of just one of the two guiding grooves 112 for the sake of brevity, but the present disclosure is not limited thereto. For example, in other embodiments of the present disclosure not shown in the drawings, the two guiding grooves 112 of the vertical slot 11 can be of different structures or can be not mirror-symmetrical relative to each other.

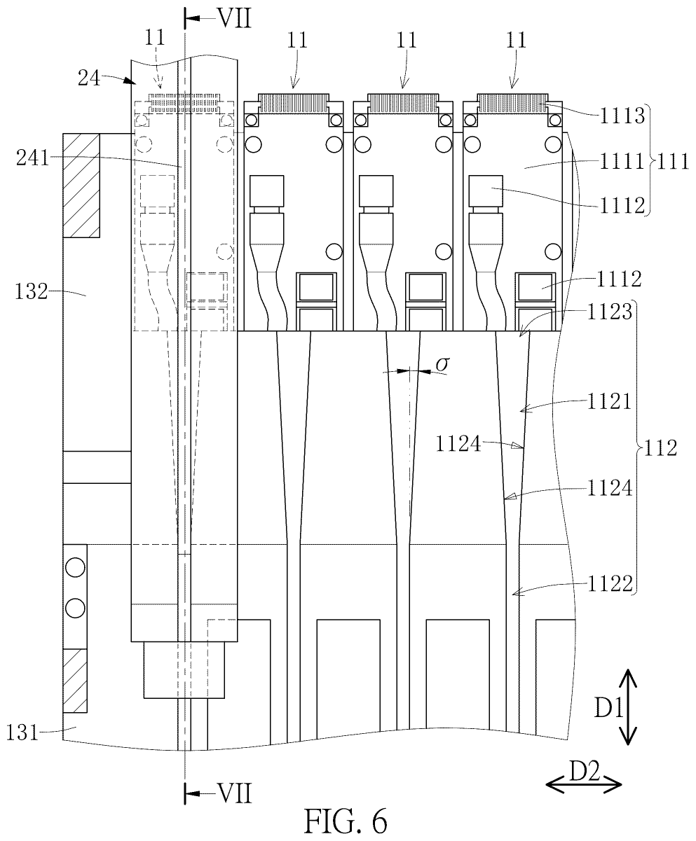

As shown in FIG. 5 and FIG. 6, the guiding groove 112 has a guiding segment 1121 recessed from the top opening 1123 and a straight segment 1122 that is recessed from the guiding segment 1121 along the vertical direction D1. In other words, along the vertical direction D1, the guiding groove 112 is sequentially formed with the guiding segment 1121 and the straight segment 1122 by being recessed from top opening 1123. Moreover, the guiding groove 112 has a first length L1 along the vertical direction D1, the guiding segment 1121 has a second length L2 along the vertical direction D1, and the second length L2 is preferably within a range from 5% to 15% of the first length L1, but the present disclosure is not limited thereto.

Specifically, a width of the guiding segment 1121 is tapered in a direction from the top opening 1123 toward the straight segment 1122 (e.g., a top-down direction shown in FIG. 6), and the straight segment 1122 has a same width. In other words, a bottom of the guiding segment 1121 has a minimum width that is substantially equal to the width of the straight segment 1122. The guiding segment 1121 has two inner side walls 1124 facing toward each other. Any one of the two inner side walls 1124 of the guiding segment 1121 and the vertical direction D1 have a guiding angle σ therebetween that is less than or equal to 5 degrees.

It should be noted that the cabinet 1 can be formed with at least part of the above structures according to practical requirements, and the cabinet 1 can also be changed arbitrarily. In order to clearly describe the present embodiment, the following description describes one possible configuration of the cabinet 1, but the present disclosure is not limited thereto.

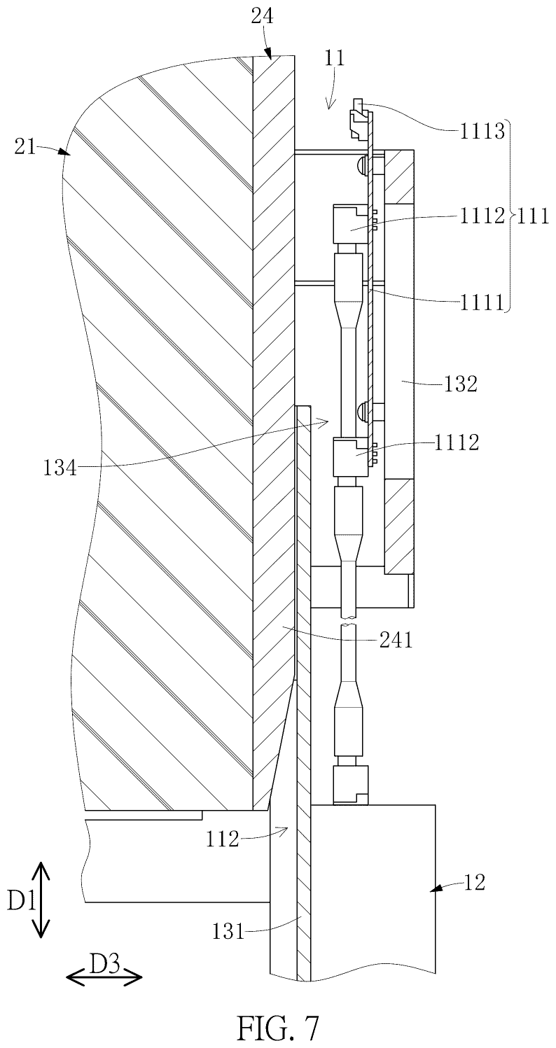

Specifically, as shown in FIG. 1, FIG. 4, and FIG. 7, the cabinet 1 includes a cabinet body 13 and a plurality of horizontal adjustment seats 14 that are assembled to a bottom of the cabinet body 13. The vertical slots 11 are formed in the cabinet body 13, and the at least one switch 12 is assembled to an outer side of the cabinet body 13 and is electrically coupled to each of the insertion ports 111. Moreover, the cabinet body 13 is provided with a plurality of holes and is configured to allow the cooling liquid to flow in or out along any direction. The horizontal adjustment seats 14 are selectively adjusted so as to enable the cabinet body 13 to be located at a level that meets practical requirements.

Specifically, the cabinet body 13 includes two guiding boards 131 facing toward each other along the width direction D3, two fixing boards 132 respectively located at two outer sides of the two guiding boards 131, and a plurality of spacing beams 133 that are connected to the two guiding boards 131 for fixing a relative position between the two guiding boards 131. The two guiding grooves 112 of each of the vertical slots 11 are respectively recessed in the two guiding boards 131, and the top opening 1123 of any one of the two guiding grooves 112 of each of the vertical slots 11 is arranged on a top edge of the corresponding guiding board 131.

Moreover, each of the two fixing boards 132 is assembled to a top portion of an adjacent one of the two guiding boards 131 so as to jointly define one of two connection grooves 134 parallel to the distribution direction D2. Each of the two connection grooves 134 is arranged outside of the guiding segment 1121 of an adjacent one of the two guiding boards 131, and the two insertion ports 111 of each of the vertical slots 11 are respectively arranged in the two connection grooves 134. In addition, the at least one switch 12 is located under at least one of the two connection grooves 134, thereby appropriately utilizing space and facilitating electrical coupling to each of the insertion ports 111.

It should be noted that a quantity of the at least one switch 12 included by the cabinet 1 in the present embodiment is two, the two switches 12 are respectively fixed to outer sides of the two guiding boards 131 and are respectively located under the two connection grooves 134, and each of the two switches 12 is electrically coupled to the insertion ports 111 arranged in an adjacent one of the two connection grooves 134, but the present disclosure is not limited thereto. For example, in other embodiments of the present disclosure not shown in the drawings, the two switches 12 can be fixed to the outer side of one of the two guiding boards 131 and can be located under an adjacent one of the two connection grooves 134 according to practical requirements; or, the quantity of the at least one switch 12 included by the cabinet 1 can be one.

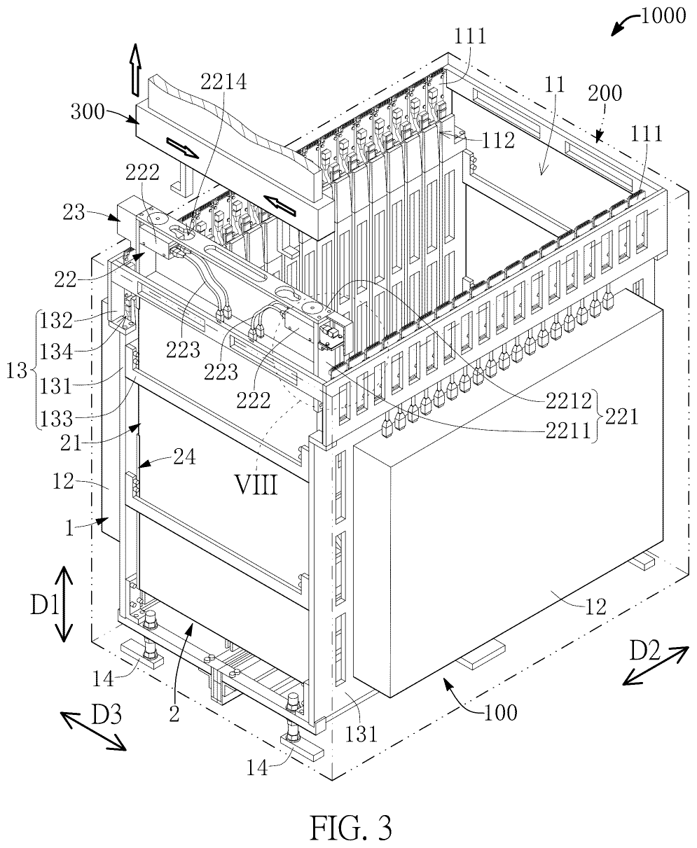

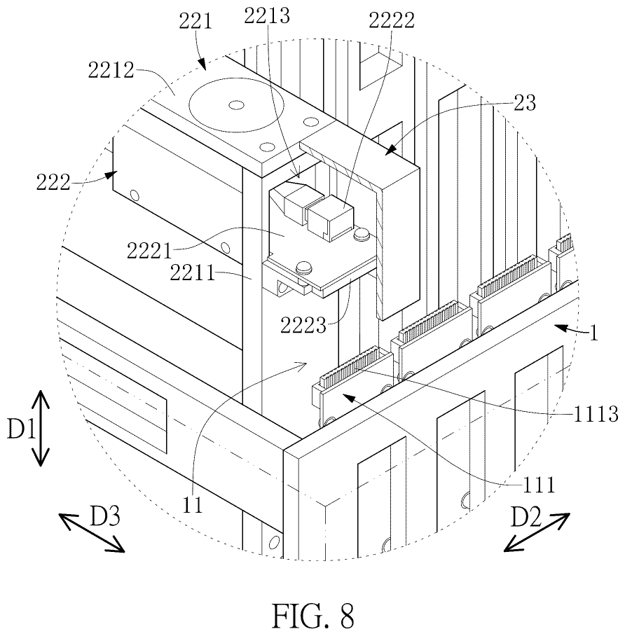

Moreover, a quantity of the at least one server module 2 included by the server apparatus 100 can be more than one, and in order to clearly describe the present embodiment, the following description and the drawings present the structure of just one of the server modules 2 and the connection relationship between the server module 2 and the corresponding vertical slot 11 for the sake of brevity. As shown in FIG. 1, FIG. 3, FIG. 8, and FIG. 9, the server module 2 includes a server 21, an external connection mechanism 22 assembled to a top portion of the server 21, at least one protective cap 23 disposed on the external connection mechanism 22, and a guiding mechanism 24 that is assembled to a bottom portion of the server 21.

Specifically, heat energy of the server module 2 is generated from the server 21, and the server 21 is substantially a rectangular box having a longitudinal direction parallel to the vertical direction D1. The server module 2 has a first height H1 along the vertical direction D1, and the server 21 has a second height H2 along the vertical direction D1. The first height H1 is preferably within a range from 105% to 125% of the second height H2, and a width of the server module 2 along the distribution direction D2 is substantially equal to a width of the server 21 along the distribution direction D2, but the present disclosure is not limited thereto.

Moreover, the external connection mechanism 22 includes a handle 221 fixed to the server 21, at least one electrical connection member 222 assembled to the handle 221, and a signal transmission unit 223 that is electrically coupled to the server 21 and the at least one electrical connection member 222. The handle 221 is fixed to the top portion of the server 21. A quantity of the at least one electrical connection member 222 is two, and the two electrical connection members 222 are respectively assembled to two opposite sides of the handle 221. The signal transmission unit 223 and a portion of each of the two electrical connection members 222 are arranged in a space that is surroundingly defined by the handle 221 and the server 21.

Specifically, the handle 221 in the present embodiment is substantially U-shaped and includes two lateral boards 2211 and a top board 2212 that is connected to the two lateral boards 2211. The two lateral boards 2211 are fixed to the top portion of the server 21, and each of the two lateral boards 2211 has a thru-hole 2213. The top board 2212 has at least one holding hole 2214 that is configured for enabling the transferring mechanism 300 to hold the server module 2.

Each of the two electrical connection members 222 in the present embodiment can include a circuit carrier 2221, a plurality of signal connectors 2222 mounted on the circuit carrier 2221, and a male connector 2223 that is mounted on a top end of the circuit carrier 2221. In any one of the two electrical connection members 222, the signal connectors 2222 and the male connector 2223 are mounted on a same surface of the circuit carrier 2221, thereby reducing a volume of the electrical connection member 222, but the present disclosure is not limited thereto. Moreover, the two electrical connection members 222 are respectively assembled to the two lateral boards 2211, and a portion (e.g., the male connector 2223) of each of the two electrical connection members 222 passes through the thru-hole 2213 of a corresponding one of the two lateral boards 2211 and is insertable into the corresponding insertion port 111 (e.g., the female connector 1113) of the vertical slot 11. Specifically, said portion of the electrical connection member 222 is an end part of the electrical connection member 222 that protrudes outward from the handle 221 and that is actually insertable into the corresponding insertion port 111.

In addition, the signal transmission unit 223 in the present embodiment includes a plurality of transmission wires that are connected to the two electrical connection members 222 (e.g., the signal connectors 2222) and the server 21, thereby enabling the server 21 to electrically couple to the male connector 2223 of each of the two electrical connection members 222.

Furthermore, a quantity and position of the at least one protective cap 23 correspond to those of the thru-hole 2213 of the handle 221. In other words, the quantity of the at least one protective cap 23 in the present embodiment is two, and the two protective caps 23 respectively correspond in position to the two thru-holes 2213, and the portion of each of the two electrical connection members 222 and the corresponding insertion port 111 are arranged in one of the two protective caps 23, but the present disclosure is not limited thereto. For example, in other embodiments of the present disclosure not shown in the drawings, a quantity of the electrical connection member 222 and a quantity of the protective cap 23 in the external connection mechanism 22 can each be only one according to practical requirements, and only one of the two lateral boards 2211 of the handle 221 is formed with the thru-hole 2213; or, the external connection mechanism 22 can be provided without the protective cap 23.

The guiding mechanism 24 in the present embodiment includes two ribs 241 respectively assembled to two opposite sides (e.g., two narrow lateral sides) of the server 21. The server 21 and the guiding mechanism 24 of the server module 2 are configured to insert into one of the vertical slots 11 along the vertical direction D1 (e.g., the two ribs 241 being respectively inserted into the two guiding grooves 112), so that each of the two electrical connection members 222 is inserted into the corresponding insertion port 111 for being located at the electrical connection position.

In summary, in the server apparatus 100 of the present embodiment, the server module 2 can be inserted into and electrically coupled to at least one of the vertical slots 11 along the vertical direction D1 through the structural design of the vertical slots 11 of the cabinet 11, such that the server module 2 and the cabinet 1 can be effectively disassembled and assembled automatically (or unmanned).

Specifically, the transferring mechanism 300 is configured to hold the server module 2 through the handle 221 (e.g., the at least one holding hole 2214) and to insert the server 21 and the guiding mechanism 24 into one of the vertical slots 11 along the vertical direction D1, so that each of the two electrical connection members 222 is inserted into the corresponding insertion port 111 for being located at the electrical connection position.

Furthermore, when the server 21 and the guiding mechanism 24 of the server module 2 are inserted into the vertical slot 11 through the transferring mechanism 300, each of the ribs 241 is guided by the corresponding guiding segment 1121 to enable the guiding mechanism 24 to correctly move to the straight segment 1122 along the vertical direction D1, and the transferring mechanism 300 is preferably configured to release the handle 221 when each of the two electrical connection members 222 is moved to be adjacent to the corresponding insertion port 111 (as shown in FIG. 8), such that each of the two electrical connection members 222 can be inserted into the corresponding insertion port 111 (as shown in FIG. 9) along the vertical direction D1 through a gravity of the server module 2. Accordingly, a collision issue that occurred by directly using the transferring mechanism 300 to insert each of the two electrical connection members 222 into the corresponding insertion port 111 can be effectively avoided.

In addition, when the server module 2 is located at the electrical connection position, the transferring mechanism 300 is configured to hold the server module 2 through the handle 221 and to separate the server module 2 from the cabinet 1 along the vertical direction D1. The transferring mechanism 300 can be any mechanism, such as: an overhead hoist transfer (OHT), a robotic arm, or an automated guided vehicle (AGV), according to practical requirements, and the present disclosure is not limited thereto.

### Second Embodiment

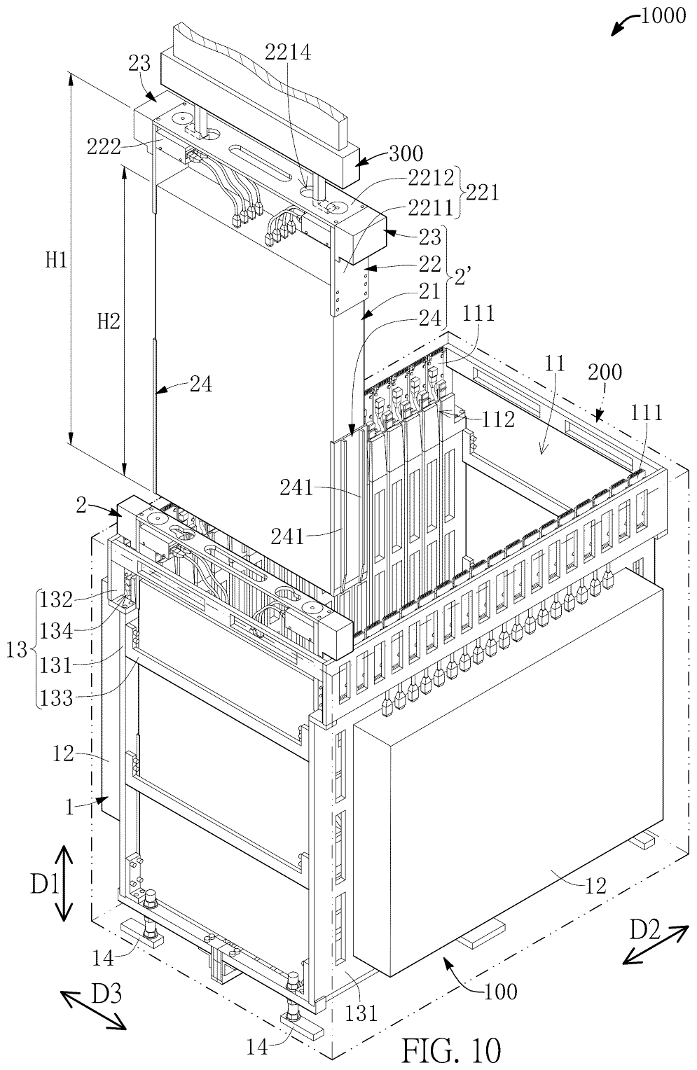

Referring to FIG. 10, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, a quantity of the server modules 2, 2′ included by the server apparatus 100 is more than one. One of the server modules 2, 2′ (i.e., the server module 2 described in the first embodiment) is detachably inserted into one of the vertical slots 11 of the cabinet 1 so as to be located at the electrical connection position, and another one of the server modules 2, 2′ (i.e., the server module 2′) is detachably inserted into at least two of the vertical slots 11 of the cabinet 1 so as to be located at the electrical connection position.

In other words, the external connection mechanism 22 and the guiding mechanism 24 provided by any one of the server modules 2, 2′ can be adjusted according to a width of the server 21 for inserting into at least two of the vertical slots 11 adjacent to each other. Moreover, according to the first embodiment and the second embodiment, the server 21 and the guiding mechanism 24 of any one of the server modules 2, 2′ can be inserted into at least one of the vertical slots 11 along the vertical direction D1.

### Beneficial Effects of the Embodiments

In conclusion, in any one of the automated immersion system, the server apparatus, and the cabinet provided by the present disclosure, the server module can be inserted into and electrically coupled to at least one of the vertical slots along the vertical direction through the structural design of the vertical slots of the cabinet, such that the server module and the cabinet can be effectively disassembled and assembled automatically (or unmanned).

Moreover, the server apparatus provided by the present disclosure can be used for the server modules of different types through the structural design of the vertical slots of the cabinet, thereby improving the flexibility and scalability of the server apparatus.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use. Alternative embodiments will become apparent to those skilled in the art to which the present disclosure pertains without departing from its spirit and scope.

What is claimed is:

1. An automated immersion system, comprising:
a cooling trough configured to accommodate a cooling liquid therein;
a server apparatus disposed in the cooling trough and including:
a cabinet including:
a plurality of vertical slots each parallel to a vertical direction, wherein the vertical slots are arranged in one row along a distribution direction perpendicular to the vertical direction, and each of the vertical slots has at least one insertion port; and
at least one switch located at an outer side of the vertical slots, wherein the at least one insertion port of each of the vertical slots is electrically coupled to the at least one switch; and
a server module that is detachably inserted into the cabinet so as to be located at an electrical connection position, wherein the server module includes:
a server;
an external connection mechanism including a handle fixed to the server, at least one electrical connection member assembled to the handle, and a signal transmission unit that is electrically coupled to the server and the at least one electrical connection member; and
a guiding mechanism assembled to the server; and
a transferring mechanism being movable relative to the cooling trough and the server apparatus, wherein the transferring mechanism is configured to hold the server module through the handle and to insert the server and the guiding mechanism into at least one of the vertical slots along the vertical direction, so that the at least one electrical connection member is inserted into the at least one insertion port of the at least one of the vertical slots for being located at the electrical connection position.

2. The automated immersion system according to claim 1, wherein, when the server and the guiding mechanism of the server module are inserted into the at least one of the vertical slots through the transferring mechanism, the at least one electrical connection member is inserted into the at least one insertion port of the at least one of the vertical slots along the vertical direction through gravity.

3. The automated immersion system according to claim 1, wherein, when the server module is located at the electrical connection position, the transferring mechanism is configured to hold the server module through the handle and to separate the server module from the cabinet along the vertical direction.

4. The automated immersion system according to claim 1, wherein the handle is fixed to a top portion of the server, and the signal transmission unit is arranged in a space that is surroundingly defined by the handle and the server.

5. The automated immersion system according to claim 4, wherein the handle includes:
two lateral boards fixed to the top portion of the server, wherein at least one of the two lateral boards has a thru-hole; and
a top board connected to the two lateral boards, wherein the top board has at least one holding hole configured for enabling the transferring mechanism to hold the server module;
wherein a portion of the at least one electrical connection member passes through the thru-hole of the at least one of the two lateral boards and is insertable into the at least one insertion port of the at least one of the vertical slots.

6. A server apparatus of an automated immersion system, comprising:
a cabinet including:
a plurality of vertical slots each parallel to a vertical direction, wherein the vertical slots are arranged in one row along a distribution direction perpendicular to the vertical direction, and each of the vertical slots has at least one insertion port; and
at least one switch located at an outer side of the vertical slots, wherein the at least one insertion port of each of the vertical slots is electrically coupled to the at least one switch; and
a server module that is detachably inserted into the cabinet so as to be located at an electrical connection position, wherein the server module includes:
a server;
an external connection mechanism including a handle fixed to the server, at least one electrical connection member assembled to the handle, and a signal transmission unit that is electrically coupled to the server and the at least one electrical connection member; and
a guiding mechanism assembled to the server;
wherein the server and the guiding mechanism of the server module are configured to insert into at least one of the vertical slots along the vertical direction, so that the at least one electrical connection member is inserted into the at least one insertion port of the at least one of the vertical slots for being located at the electrical connection position.

7. The server apparatus according to claim 6, wherein each of the vertical slots has two guiding grooves respectively arranged on two opposite sides thereof, wherein the at least one insertion port of each of the vertical slots is higher than a top opening of any one of the two guiding grooves along the vertical direction, wherein the guiding mechanism includes two ribs respectively assembled to two opposite sides of the server, and wherein the two ribs of the server module are configured to respectively insert into the two guiding grooves of the at least one of the vertical slots.

8. The server apparatus according to claim 7, wherein, in any one of the vertical slots, each of the two guiding grooves has a guiding segment recessed from the top opening and a straight segment that is recessed from the guiding segment along the vertical direction, and wherein, in each of the guiding grooves, a width of the guiding segment is tapered in a direction from the top opening toward the straight segment, and the straight segment has a same width.

9. The server apparatus according to claim 8, wherein, in each of the two guiding grooves of any one of the vertical slots, the guiding segment has two inner side walls facing toward each other, and any one of the two inner side walls of the guiding segment and the vertical direction have a guiding angle therebetween that is less than or equal to 5 degrees.

10. The server apparatus according to claim 8, wherein, in any one of the vertical slots, each of the two guiding grooves has a first length along the vertical direction, the guiding segment of each of the two guiding grooves has a second length along the vertical direction, and the second length is within a range from 5% to 15% of the first length.

11. The server apparatus according to claim 7, wherein the two guiding grooves of each of the vertical slots are mirror-symmetrical relative to each other.

12. The server apparatus according to claim 7, wherein a quantity of the at least one insertion port of each of the vertical slots is two, and wherein the two insertion ports of each of the vertical slots are respectively arranged adjacent to the two guiding grooves and are respectively located outside of the two guiding grooves.

13. The server apparatus according to claim 6, wherein the server module has a first height along the vertical direction, the server has a second height along the vertical direction, and the first height is within a range from 105% to 125% of the second height.

14. The server apparatus according to claim 6, wherein the handle is fixed to a top portion of the server, and the signal transmission unit is arranged in a space that is surroundingly defined by the handle and the server.

15. The server apparatus according to claim 14, wherein the handle includes:
two lateral boards fixed to the top portion of the server, wherein at least one of the two lateral boards has a thru-hole; and
a top board connected to the two lateral boards, wherein the top board has at least one holding hole;
wherein a portion of the at least one electrical connection member passes through the thru-hole of the at least one of the two lateral boards and is insertable into the at least one insertion port of the at least one of the vertical slots.

16. The server apparatus according to claim 15, wherein the server module includes at least one protective cap corresponding in position to the thru-hole, and wherein the portion of the at least one electrical connection member and the corresponding insertion port are arranged in the at least one protective cap.

17. The server apparatus according to claim 6, wherein a quantity of the server module included by the server apparatus is more than one, and wherein one of the server modules is detachably inserted into one of the vertical slots of the cabinet so as to be located at the electrical connection position, and another one of the server modules is detachably inserted into at least two of the vertical slots of the cabinet so as to be located at the electrical connection position.

18. A cabinet of an automated immersion system, comprising:
a plurality of vertical slots each parallel to a vertical direction, wherein the vertical slots are arranged in one row along a distribution direction perpendicular to the vertical direction, and each of the vertical slots has two insertion ports and two guiding grooves that are respectively arranged adjacent to the two insertion ports, and wherein, in any one of the vertical slots, each of the two insertion slots is higher than a top opening of an adjacent one of the two guiding grooves along the vertical direction; and
at least one switch located at an outer side of the vertical slots, wherein the two insertion ports of each of the vertical slots are electrically coupled to the at least one switch.

19. The cabinet according to claim 18, further comprising:
a cabinet body, wherein the vertical slots are formed in the cabinet body, and the at least one switch is assembled to an outer side of the cabinet body, and wherein the cabinet body is configured to allow a cooling liquid to flow in or out along any direction; and
a plurality of horizontal adjustment seats assembled to a bottom of the cabinet body.

20. The cabinet according to claim 19, wherein the cabinet body includes:
two guiding boards facing toward each other along a width direction that is perpendicular to the vertical direction and the distribution direction, wherein the two guiding grooves of each of the vertical slots are respectively recessed in the two guiding boards; and
two fixing boards respectively located at two outer sides of the two guiding boards, wherein each of the two fixing boards is assembled to a top portion of an adjacent one of the two guiding boards so as to jointly define one of two connection grooves parallel to the distribution direction, and wherein the two insertion ports of each of the vertical slots are respectively arranged in the two connection grooves, and the at least one switch is located under at least one of the two connection grooves.
